(19) United States
(12) Patent Application Publication
(10) Pub. No.: US 2007/0020793 A1
(43) Pub. Date: Jan. 25, 2007

(54) Three-dimensional shaped solid dosimeter and method of use

(76) Inventor: John A. Adamovics, Skillman, NJ (US)

Correspondence Address: MATHEWS, SHEPHERD, MCKAY, & BRUNEAU, P.A., 29 THANET ROAD, SUITE 201, PRINCETON, NJ, 08540, US

(21) Appl. No.: 11/507,281

(22) Filed: Aug. 21, 2006

Related U.S. Application Data
(63) Continuation-in-part of application No. 10/790,280, filed on Mar. 1, 2004, now Pat. No. 7,098,463.

(51) Int. Cl. H01L 21/00

(52) U.S. Cl. 438/48

(57) ABSTRACT

The invention relates to a solid plastic three-dimensional dosimeter which is useful in treatment planning, optimization of the radiation field, dose verification, dose validation, commissioning, and quality assurance of complex radiotherapeutic procedures. Dosimeters of the invention can be formed in any clinically relevant shape, and contain a reporter leuco dye which forms a colored image upon irradiation.

### CROSS REFERENCE TO RELATED APPLICATION

This application is a continuation in part of U.S. patent application Ser. No. 10/790,280, filed Mar. 1, 2004, the entirety of which is hereby incorporated by reference into this application.

### BACKGROUND OF THE INVENTION

1. Field of the Invention

The present invention relates to dosimeters and in particular to a three-dimensional shaped solid dosimeter and method of use.

2. Description of Related Art

In the field of radiotherapy of human cancer it is important to plan the intensity, duration, dose, and target volume of radiation to achieve optimal impact upon the target tumor and minimal exposure of nearby normal tissue. Recently, complex radiotherapy regimens such as three-dimensional conformal radiotherapy (3DCRT) and intensity-modulated radiotherapy (IMRT) have found increased use in radiation oncology. The IMRT technique is a method which delivers doses of radiation to conform to irregularly shaped tumor volumes while minimizing the dose to nearby critical structures. IMRT offers the possibility of high dose gradients, and it is therefore possible to deliver high doses to target volumes while maintaining very low doses to nearby critical normal structures to a much greater extent than is the case with conventional radiation therapy. The high gradients achievable with IMRT mean that localization of the dose distribution is critical. Small errors in delivery of the dose can mean that a target volume is missed, or that a sensitive normal structure is irradiated to a higher dose than intended, and perhaps higher than can be tolerated. Therefore these complex radiotherapy procedures require sophisticated treatment planning, optimization of the radiation field, and verification of the delivery of the planned dose before the patient is subjected to radiotherapy. It is desirable to have the ability to measure the effects of the planned treatment fields with high accuracy and sensitivity in a three-dimensional volume of clinically relevant dimensions.

Different diseases and different modes of radiotherapy require various sizes of dosimeters. A clinically relevant dosimeter may be as small as a cylinder having a 5 mm diameter and a 20 mm height, or as small as a shaped solid of a volume of about 1 cm³. For other applications, large dosimeters such as a cylinder having a diameter of about 20 cm and a height of about 40 cm, or such as a shaped solid of a volume of about 40 liters can be used. Large dosimeters can also be formed in shapes currently in use in the Bottle Manikin Absorption (BOMAB) Calibration Phantom (Analytics, Inc., Atlanta Ga.). Examples of BOMAB phantom shapes include the head (ellipsoid cross section 19×14 cm, height 20 cm, volume 3525 ml), the neck (circular cross section of 13 cm, height 10 cm, volume 1030 ml) and the chest (ellipsoid cross section 30×20 cm, height 40 cm, volume 16970 ml). A substantially cylindrical dosimeter with clinically relevant dimensions has a range of diameters of 5 mm to 20 cm, and a range of heights from 20 mm to 40 cm. A shaped solid dosimeter with clinically relevant dimensions has a range of volumes from about 1 cm³ to about 40 liters.

The commissioning as well as routine quality assurance (QA) of treatment techniques such as IMRT and 3DCRT requires a dosimeter which can accurately and conveniently measure dose distributions also in three dimensions. Conventional IMRT QA dosimetry systems, such as Mapcheck and Radiation Imaging Technology, perform only a limited 2D dose measurement in practice. A need has therefore arisen for an accurate and convenient 3D dosimetry system that can more effectively and comprehensively commission and perform routine QA for these techniques (Guo et al, Med. Phys. 2006, 33(5), 1338-1345).

Since the advent of radiotherapy, medical physicists have utilized dosimeters of various types to measure the intensity and field of impact of radiation. Dosimeters as diverse as ion chambers, two-dimensional photographic film, two-dimensional radiographic film, thermoluminescent plates, and phosphor plates have been used. Conventional metal oxide semiconductor field effect transistors (MOSFET) and thermoluminescent devices (TLD) are used to quantitate radiation at discreet points in a radiation field. However, the above-described conventional dosimeters have the limitation of not being capable of measurement of radiation in three dimensions due to the physical restrictions of their design.

Attempts have been made to measure radiation fields in three dimensions. Photographic and radiographic films have been arrayed by stacking or otherwise organizing to produce a series of two-dimensional slices across a three-dimensional volume. This approach suffers from the drawbacks that the radiation field in between the slices cannot be measured and there are difficulties in assembling and positioning several films, it is time-consuming for disassembly, scanning, and interpretation of the film array, and in the inherent error in radiation measurement due to the heterogeneity of the devices.

Three-dimensional dosimeters have been fabricated from aqueous gels containing chemical substances which change properties upon exposure to radiation. The change in properties has been detected by spectrophotometry, optical scanning, and magnetic resonance imaging. The data contained in gel dosimeters after irradiation, when measured by optical scanning, is evaluated as optical contrast generated by light scattering by the irradiated regions of the gel that are translucent. Alternatively, gel dosimeters can be scanned using complex and expensive magnetic resonance imaging instrumentation. Although gel dosimeters can be prepared in volumes large enough to be clinically relevant, they have the disadvantage that they need to be contained in a vessel, which adds to the expense of the device and poses difficulties in the placement and scanning of irradiated dosimeters. Due to the nature of the formulation of radiochromic gel dosimeters, the image formed upon irradiation is dimensionally unstable and diffuses through the matrix resulting in compromised accuracy and sensitivity. Some gel dosimeters are thermally unstable and melt or coalesce at warm temperatures. In some cases the full response of gel dosimeters to radiation is not complete until 24 to 48 hours post-irradiation.

Although gel dosimetry has been applied in the commissioning and QA of IMRT and other complex radiotherapeutic techniques, many problems such as, inter alia, diffusion, susceptibility to oxygen and ambient light sources, susceptibility to light scattering artifacts, and the need for a container have limited the usefulness of dosimeters fabricated from gels.

A thin leuco dye polymeric film has been described in U.S. Pat. No. 5,206,118. A formulation containing certain leuco dyes in an organosol containing a halogen-containing polymer is knife-coated onto a support, then heated to drive off solvent and cure the polymeric residue. Interaction of the film with radiation provides a colored two-dimensional pattern, such as words or symbols. The leuco dyes of the triarylmethane type described in U.S. Pat. No. 5,206,118 do not to provide acid sensitivity and were found to be not useful. The limitations for this type of dosimetry for clinical radiotherapy include the need for expensive mixing machinery, the need for heating the film dosimeter, and the volume limitations inherent in a knife-plating and curing film technique.

U.S. Pat. No. 5,498,876 describes a solid polymeric dosimeter which is pre-activated by a particular laser light. In this dosimeter a light-sensitive dopant molecule, dispersed throughout the medium, is subjected simultaneously to two laser beams at right angles to each other which traverse the volume of the dosimeter. The dopant molecule interacts simultaneously with two photons, and is thereby transformed to an unstable, higher-energy state. Upon irradiation with high-energy radiation such as neutron beam, the high-energy molecule is induced to revert back to its low-energy form. This reversion is accompanied by fluorescence, which is detected. This dosimeter, sensitive to light, is enclosed in an opaque holder. Designed to be useful as a neutron dosimeter, this device suffers from the limitations of room-temperature instability of the high-energy state of the activated dosimeter, and from the necessity to pre-activate the dopant molecules with expensive machinery. The volume limitations of such a device are described (Moscovitch et al, Radiation Protection Dosimetry 2002, 101, 17-22.) In this work, film dosimeters in the range of 100 um thick to “bulk materials” having a thickness of a centimeter or more are described. Such tiny devices have little or no clinical relevance. These aspects render this sort of device cumbersome and difficult to manipulate for use in radiotherapy treatment planning and other aspects of radiotherapy using dosimetry.

Accordingly, there is an unmet need for a three-dimensional dosimeter which is capable of meeting the demands of complex radiotherapy, including treatment planning and optimization, dose verification, dose validation, commissioning, and quality assurance. There is a need for a three-dimensional dosimeter which can be formed in any clinically relevant shape, which can be used without a container, and which can be stored before and after use for a reasonable amount of time without detriment to its efficacy. There is a need for a three-dimensional dosimeter which is homogeneous across all its dimensions, which is stable to reasonable shipping and handling conditions, and which can easily be used by medical dosimetrists without assembling into an array or pre-activating with complex and expensive equipment. Further, there is a need for a three-dimensional dosimeter which is at once sensitive and robust, one which can accurately record the wide ranges of radiation intensity utilized in various radiological procedures by providing a stable, non-diffusing colored image within a substantially transparent volume.

### SUMMARY OF THE INVENTION

The invention relates to a shaped solid three-dimensional dosimeter of clinically relevant volume comprising an optically clear plastic containing one or more reporter compounds and, optionally, one or more activators; and to the use of the dosimeter to measure, in three dimensions, radiation fields used in the planning, optimization, and treatment of disease. The invention further relates to the optical computerized tomographic scanning of the dosimeter in which the absorbance of light by the image formed within the dosimeter as a result of the radiation is measured.

The optically clear plastic of the present invention is discriminated from conventional dosimetric gels. Conventional dosimetric gels are translucent, prepared from aqueous precursors, and must be constrained in a container. The optical plastic of the present invention is substantially transparent, formed from water-insoluble precursors, and is fabricated into any desired shape without the need for a container in the finished dosimeter. The present invention provides a dosimeter which is formulated from water-insoluble prepolymers and one or more water-insoluble color-forming reporter molecule resulting in a shaped solid substantially transparent optical plastic in which a colored image forms upon irradiation. The present invention provides a shaped solid three-dimensional dosimeter which is used without a container and which is stable to room temperature handling, and room temperature pre- and post-irradiation storage. The present invention provides a shaped solid three-dimensional dosimeter which is substantially transparent throughout both before and after irradiation.

It was found that several dyes, when admitted into a polymer of a polyurethane plastic matrix, gave unacceptably high background color (before irradiation) or were incompatible with the polymer components. Some potential reporter molecules displayed unacceptably low solubility in the polyurethane. Other dyes, although soluble in the polyurethane, gave poor color transformation parameters upon irradiation. The dyes which imparted less dose sensitivity included fluoran leuco dyes, tetrazolium salts, spiropyrans, spirobenzopyrans, and chromenes. Surprisingly, it was found that when a polyurethane dosimeter was fabricated with leucomalachite green (LMG) or leuco crystal violet (LCV) and chloroform, the resulting dosimeter exhibited a colored image within a transparent dosimeter upon irradiation with x-rays.

Optimization of the formulation with various diisocyanates, various polyols, various concentrations of LMG or LCV, various sequences of addition of reactants, the addition of various activators, various reaction temperatures, and various curing conditions led to the discovery of hard transparent dosimeters which provided a useful, high-resolution color image upon x-ray irradiation. The dosimeter exhibited the desired properties of sensitivity to low levels of x-ray radiation and relative insensitivity to ambient room light. The present invention provides a solid substantially transparent optical plastic dosimeter which can be formed into any shape.

The present invention provides a dosimeter which gives a spatially accurate, dimensionally stable, non-diffusing image representative of the field of radiation to which it is subjected.

The present invention relates to a shaped solid three-dimensional dosimeter with a high sensitivity to therapeutic radiation and relatively low sensitivity to light. The dosimeters of the present invention give a linear dose response to does of radiation which are clinically relevant, in the range of 0.1 Gy to 100 Gy.

The shaped solid three-dimensional dosimeter requires no formulation or pre-activation by the user prior to irradiation. The present invention provides a shaped solid three-dimensional dosimeter which can be scanned directly after irradiation, requiring no incubation period.

In another aspect of the present invention, a method of planning and optimizing complex radiation therapy is disclosed in which a water-insoluble substantially transparent shaped solid dosimeter having one or more water-insoluble reporter molecules distributed homogeneously throughout is subjected to a field of radiation, resulting in the formation of a colored image within the volume of the dosimeter. The colored image is analyzed by computerized optical scanning of the volume of the dosimeter. The analysis is comprised of detection of the difference in optical absorbance of light by the colored image and the optical absorbance of light by non-irradiated portions of the dosimeter. The tomographic process comprises detection of the difference in absorbances, rotating the dosimeter through a discreet angle, repeating the detection of the difference in absorbances, repeating the rotation and detection of the differences in absorption a plurality of times, and reconstructing the colored image by a computerized process.

The invention will be more fully described by reference to the following drawings.

### BRIEF DESCRIPTION OF THE DRAWINGS

FIG. 1 is a graph of dose response of dosimeters made with leuco dye of Structure III. Measurement is at 633 nm.

FIG. 2 is a graph of Dose Response of dosimeters made with leuco dye of Structure III. Measurement is at 633 nm.

FIG. 3 is a graph of dosimeters containing 3% w/w leuco dyes of the present invention. The leuco dyes were prepared in 2 cm (dia.) glass vials and irradiated with 3 Gy x-rays.

FIG. 4 is a graph of sensitivity of various leuco dyes compared to leucomalachite green of Structure III.

FIG. 5 is a graph of stability of image generated in dosimeters containing leuco dyes of the present invention.

FIG. 6 is a graph of a comparison of the stability of leuco dyes of the present invention.

FIG. 7A illustrates the dose distribution calculated by a treatment plan of the present invention.

FIG. 7B illustrates the corresponding dose distribution measured by the by the dosimeter of the present invention. Isodose lines (95%, 90%, 70%, 50%, 35%, and 30% from central region to outer region) were superimposed on both images of FIG. 7A and FIG. 7B respectively.

FIG. 7C illustrates profiles for the calculated dose distribution (solid line) and the measurement of dosimeters of the present invention (dotted line) along the solid line.

FIG. 7D illustrates an overlay of the isodose lines (95%, 90%, 70%, 50%, 35%, and 30%) from the calculation dose distribution (dark solid line) and the measurement of the dosimeter of the present invention (light solid line).

### DETAILED DESCRIPTION

Reference will now be made in greater detail to a preferred embodiment of the invention, an example of which is illustrated in the accompanying drawings. Wherever possible, the same reference numerals will be used throughout the drawings and the description to refer to the same or like parts.

The shaped solid dosimeter of the present invention comprises an optical plastic having a color-forming reporter molecule distributed throughout in a homogeneous fashion. The reporter molecule is soluble in the plastic formulation but insoluble in water.

The shaped solid dosimeter can be formed by allowing homogeneous liquid prepolymer mixtures containing a dissolved color-forming reporter to cure within the confines of a mold. Once cured to a hard substantially transparent plastic, the dosimeter can be freed from the mold. Alternatively, the dosimeter can be formed by other methods which are well known by those skilled in the art.

In some embodiments of the invention it is desirable to introduce modifications to the shaped solid dosimeter. Modifications include, but are not limited to, ridges, channels, troughs, holes, furrows, chases, bevels, and chamfers. These modifications can be useful in orienting the dosimeter within a scanning instrument, or in orienting the dosimeter into a holder, such as a phantom, used during irradiation. These modifications can be useful in providing for insertion of materials within the dosimeter including MOSFET devices, TLD devices, registration mating pins, fiducial pins, and the like. Metal Oxide Semiconductor Field Effect Transistors (MOSFET), thermoluminescent devices (TLD), registration mating pins, and fiducial pins are well-known in the art. These modifications can be introduced into the hard plastic dosimeter by a molding process or by common mechanical techniques such as drilling, lathing, cutting, tapping, and routing. The invention thus provides a hard plastic non-gel dosimeter, having no external container, which can be formed in any shape and which can be tooled after curing.

In an embodiment of the invention, the shape of the dosimeter can be designed to be used as a simple phantom for the treatment planning and optimization of radiation therapy for human disease. A simple phantom is herein defined as a homogeneous substance which has a defined shape useful in the treatment planning and optimization of radiation therapy for human disease. A simple phantom is used by placing the phantom in such a position within the treatment radiation field so as to mimic the target volume of the patient to be treated.

In another embodiment of the invention, the shape of the dosimeter can be designed to be useful when inserted within an anthropomorphic phantom used in the treatment planning and optimization of radiation therapy for human disease. Anthropomorphic phantoms can have shapes resembling that of the human body and may have structures mimicking human organs. An “anthropomorphic phantom” is herein defined as a device intended to support the positioning of a dosimeter such that its placement is optimal for radiation therapy planning and optimization. Anthropomorphic phantoms for which dosimeters of the invention may be useful include, for example, the radiosurgery head phantom (Computerized Imaging Reference Systems, CIRS, Norfolk, VA), thorax phantom (CIRS), pelvic 3D phantom (CIRS), head and neck phantom (CIRS), the Lucy® 3D phantom (Fluke Biomedical, Cleveland, Ohio), the ATOM® Phantom (CIRS) and RANDO phantom (The Phantom Laboratory, Salem, N.Y.).

“Hard substantially transparent plastic” is herein defined as a polymer composition having the property of transmitting light without appreciable scattering possessing such three-dimensional rigidity as to prevent distortion by normal handling consistent with use as outlined in the invention. For example, a liquid, gum, gel, or semisolid polymer composition would not constitute a “hard substantially transparent plastic.” For example, a cloudy, opaque, translucent, frosted, or etched polymer composition would not constitute a “hard substantially transparent plastic”. “Shaped solid” is herein defined as a volume of polymer composition possessing a defined shape which will not distort through normal handling consistent with use as outlined in the invention. For example, a gel or liquid material confined in a container or a film deposited upon a substrate would not constitute a “shaped solid”.

It was discovered that not all optical plastics are suitable matrices for the invention. The formation of some optical polymers is accompanied by the release of energy as heat. It was found that, when preparing some dosimeters of a clinically relevant volume, the exotherm accompanying the formation of certain polymers was unacceptably high. Temperatures in excess of about 60° C. caused premature coloring or decomposition of the reporter compounds. Optical polymers which exhibit unacceptable exotherms (i.e., producing temperatures in excess of 60° C.) include polyesters, polystyrenes, epoxy resins, and polyacrylates. It was discovered that certain polyurethane formulations which resulted from reaction of selected diisocyanates with appropriate polyols formed substantially transparent optical plastic without a detrimental exotherm, and were thus compatible with certain color-forming reporter molecules. It will be appreciated that other optical plastics can be induced to form and cure at temperatures compatible to form dosimeters which are within the scope of the invention.

According to the invention, the selected reporter molecule, distributed throughout the dosimeter, gives a color reaction upon radiation. Owing to extremes of radiation intensity utilized in complex radiotherapeutic procedures, it is critical that the reporter provide a high degree of sensitivity (a high degree of color change upon low levels of irradiation).

It is desirable to provide a high degree of spatial accuracy because of the proximity of normal tissues to target cancer tissues. The reporter molecule, when distributed throughout the dosimeter before irradiation, imparts no color or a faint transparent color. Once irradiated, the reporter forms a colored image which is representative of the radiation field applied. The color image proved to be stable in that it persisted over time and did not diffuse within the volume of the dosimeter.

One method of formulating the dosimeter provides a high level of control over the temperature, mixing, molding, and curing parameters of the fabrication of the dosimeter. In this method, one or more chemical precursors to the polymeric product, such as prepolymers, are mixed with one or more polymerization catalysts, one or more reporter molecules, optionally a solvent, and optionally one or more activators to provide a mixture which is placed into a mold and allowed to polymerize under controlled conditions, thereby providing the solid molded dosimeter of the present invention.

Prepolymers are defined herein as chemically reactive precursors which form, under the reaction conditions of the invention, a copolymer, also referred herein as a substantially transparent polymer, possessing desirable and useful physical properties to practice the invention. A polymerization catalyst is defined herein as a chemical entity used to accelerate the copolymerization of the prepolymers, enabling the process to take place under controlled conditions of reaction temperature and duration.

In this method, the optical plastic is synthesized in situ from monomeric or oligomeric precursor(s) in the presence of the other chemical components of the present invention. The nature of the precursor(s) and the catalyst to promote the polymerization reaction are dictated by the choice of the optical plastic, and are known to those of ordinary skill in the art. In this method, the present invention can provide a process for a controlled reaction rate between the monomers or prepolymers for optimizing heat released by the reaction during the process, time required to complete the process, and physical parameters defining the product polymer.

The present invention provides a process in which one or more reporter molecules contained within a polymer product remains in an original, native, or leuco state throughout the manufacturing process, and is not altered in its molecular structure by the process. The present invention optionally provides a product containing within the polymeric matrix one or more activators which, upon interaction with absorbed radiation, facilitates the change in optical properties of the reporter molecule, thus giving rise to a 3D dosimetric map. In one embodiment, an activator is distributed throughout the optical plastic to provide a dosimeter which is more sensitive to the field of radiation to which it is exposed than is the dosimeter lacking the activator. In another embodiment, the activator is not used and the leuco dye is transformed adequately to the colored form even in the absence of an activator.

Optical plastics can be formed through polymerization of a monomer in the presence of an initiator. Also, optical plastics are often formed by contacting two or more prepolymers which react, often in the presence of a catalyst, to provide a polymeric product. Prepolymers useful for this invention include chemically complimentary precursors which, upon mixing and incubation under the conditions of the present invention, react to form a polymeric product with desirable and useful properties.

A suitable polymeric matrix for the present invention is polyurethane. In this embodiment, a Prepolymer A is a diisocyanate and a Prepolymer B is a polyol. In the polymerization process, one hydroxyl group of the polyol reacts with one isocyanate group of the diisocyanate to form a urethane bond. Polymerization proceeds as subsequent hydroxyls and isocyanates react. Typically, polyurethanes have been formed by the reaction of Prepolymer A with Prepolymer B in the presence of a polymerization catalyst. Any or all of Prepolymer A, Prepolymer B, and the catalyst can be dissolved in varying amounts of solvent. It is well known to those of ordinary skill in the art that the nature and amount of solvent can contribute to the properties of the polymer product.

It has also been discovered that polyurea formulations provide optical plastics which are substantially transparent and which are useful in the present invention. These polyureas are formed by the reaction under controlled conditions of diisocyanates with sterically hindered secondary amines, such as polyaspartate esters, as described in U.S. Pat. No. 5,126,170 hereby incorporated by reference into this application. Such compounds or their functional equivalents can be employed to provide the polymeric matrix of the invention, and are known as, for example, Desmophen NH 1220, Desmophen NH 1420, and Desmophen NH 1520 (Bayer).

In contrast to the invention disclosed in U.S. Pat. No. 5,206,118, discussed above, wherein triarylmethane dyes were found not useful, selected triarylmethane leuco dyes have been found to work well in the present invention. Suitable reporter molecules for use in the present invention are leuco dyes of the triarylmethane type which are herein defined as compounds that are essentially free of color and which have a structure corresponding to 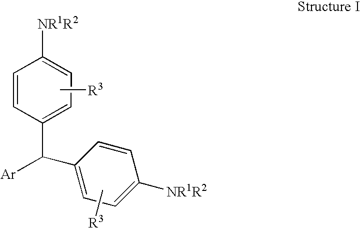
wherein R¹ and R² are H, lower alkyl of C₁-C₆, or phenyl; R³ is H, lower alkyl of C₁-C₆, or phenyl, substituted at the ortho or meta position; and Ar is aromatic or heteroaromatic. Ar can be Ar is a carbocyclic aromatic or a 5, 6, or 7-membered heterocyclic ring containing one or two heteroatoms selected from N, O, and S.

In one embodiment, the invention comprises a solid dosimeter formed of an optical transparent and a reporter molecule of the structure 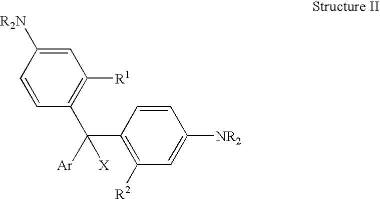
wherein
R is methyl, ethyl, propyl, butyl, or phenyl;
R¹ is H, C₁-C₆ alkyl, or phenyl;
R² is H, C₁-C₆ alkyl, or phenyl;
Ar is phenyl, o-tolyl, 2,6-dimethylphenyl, 2-methoxyphenyl, 4-methoxyphenyl, 2-hydroxyphenyl, 4-hydroxyphenyl, 4-phenylaminophenyl, 4-diphenylaminophenyl, 2,4-dimethoxyphenyl, 2-fluoro-4-methoxyphenyl, 1-napthyl, 4-dimethylamino-1-napthyl, 4-diethylamino-1-napthyl, 4-phenylaminophenyl-1-napthyl, 4-diphenylaminophenyl-1-napthyl, 2-napthyl, anthracene-9-yl, 2-fluorophenyl, 2-chlorophenyl, 2-bromophenyl, 2,6-difluorophenyl, 2-methoxyphenyl, 4-dimethylaminophenyl, 4-diethylaminophenyl, pentafluorophenyl, furan-2-yl, furan-3-yl, 2-thiophenyl, 4-thiophenyl, thiophene-2-yl, thiophene-3-yl, 2-indolyl, 3-indolyl, 5-indolyl, 2-pyridyl, 3-pyridyl, 4-pyridyl, imidazol-2-yl, 2-biphenyl, 3-biphenyl, 4-biphenyl, pyrrole-2-yl, pyrrole-3-yl, imidazol-4(5)-yl, 4-(1H-imidazol-1-yl)phenyl; and

X is H, nitrilo, hydroxyl, azido, pyrrole-1-yl, imidazol-2-yl, methoxy, ethoxy, tert-butoxy, phenoxy, 4-fluorophenoxy, 4-methoxyphenoxy, p-methoxybenzyl, methylthio, and phenylthio.

It was discovered that the triarylmethane leuco dyes having Structure II generally are useful reporter molecules in the present invention.

In one embodiment, the present invention comprises a shaped solid dosimeter formed of an optical transparent plastic and a reporter molecule of the structure

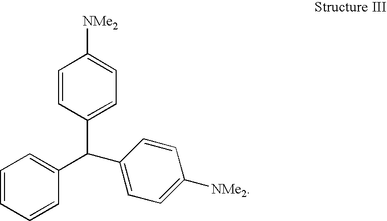

In an alternate embodiment, the present invention comprises a shaped solid dosimeter formed of an optical transparent plastic and a reporter molecule of the structure

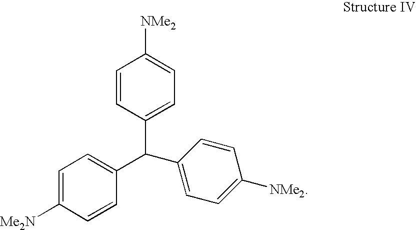

An alternate embodiment of the present invention comprises a shaped solid dosimeter formed of an optical transparent plastic and a reporter molecule of the structure

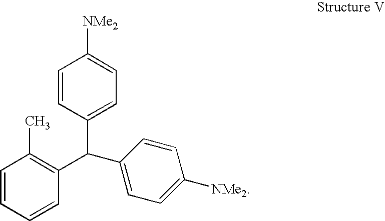

An alternate embodiment of the present invention comprises a shaped solid dosimeter formed of an optical transparent plastic and a reporter molecule of the structure

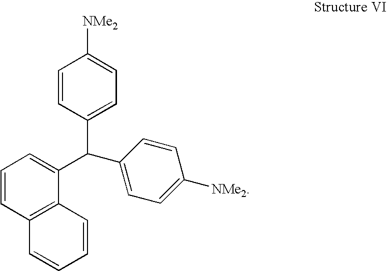

An alternate embodiment of the present invention comprises a shaped solid dosimeter formed of an optical transparent plastic and a reporter molecule of the structure

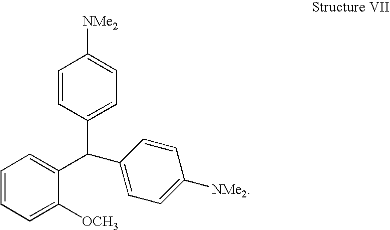

An alternate embodiment of the present invention comprises a shaped solid dosimeter formed of an optical transparent plastic and a reporter molecule of the structure

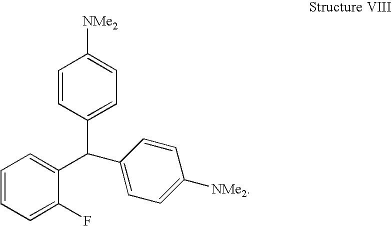

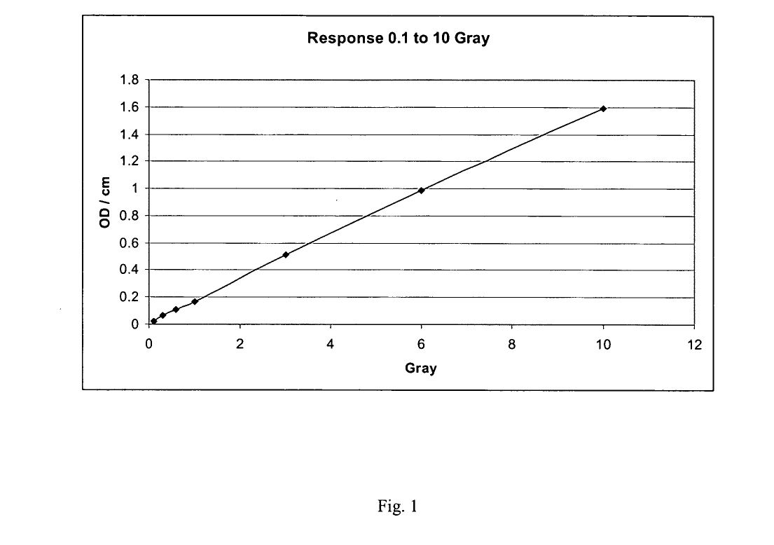

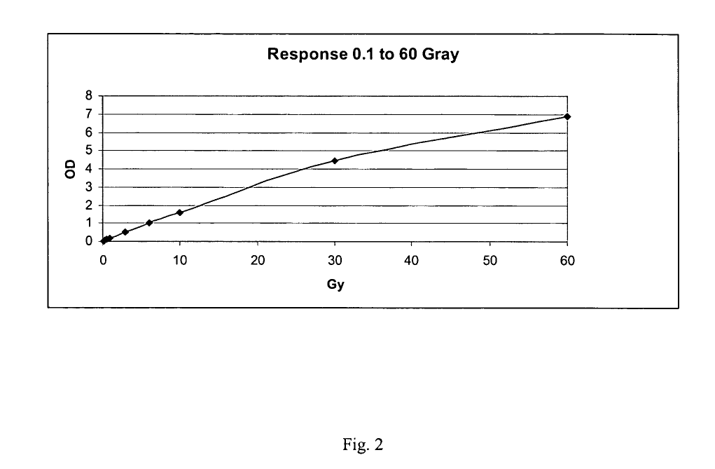

It is desirable that a dosimeter give linear dose-response over the range of intended radiation intensity. It was found that dosimeters fabricated from polyurethane and a leuco dye compound of the present invention demonstrated a linear dose-response over a wide range of intensities. FIG. 1 displays the response of the dosimeter including Structure III to radiation ranging from 0.1 Gray to 10 Gray. FIG. 2 shows that a slight deviation from linearity is found at doses exceeding 30 Gray. These ranges are in accord with that which is employed in conventional 3D conformal radiation therapy.

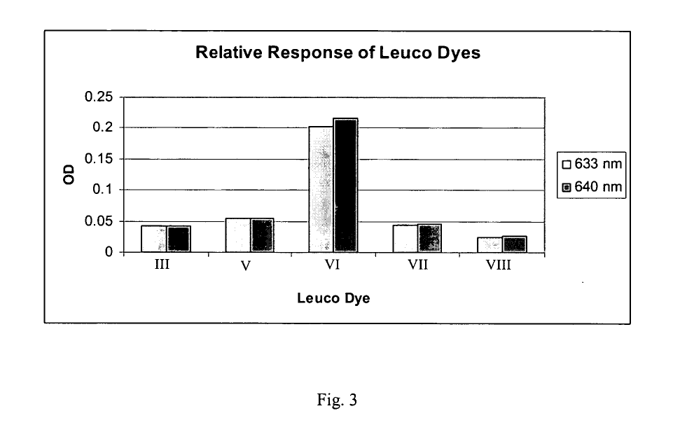

It was found that certain triarylmethane leuco dyes demonstrated especial advantage. Surprisingly, leuco dyes of Structures V and VI provided dosimeters when formulated in polyurethane which were significantly more sensitive to radiation than the dosimeter formulated with leuco dye having Structure III. This is demonstrated by a comparison of the response of dosimeters fabricated from equimolar amounts of leuco dyes having Structures III, V, VI, VII, and VIII irradiated and measured spectrophotometrically in an identical fashion, as shown in FIG. 3. The absorbance of the dosimeters was measured at 633 and 640 nm. The results indicate that dyes having Structures V and VI give an enhanced response, a dye having a Structure VIII, gives a diminished response, and a dye having a Structure VII gives a response about equal to a dye having Structure III.

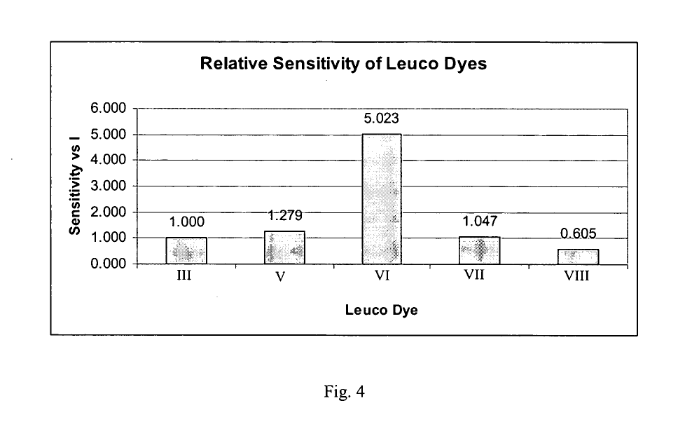

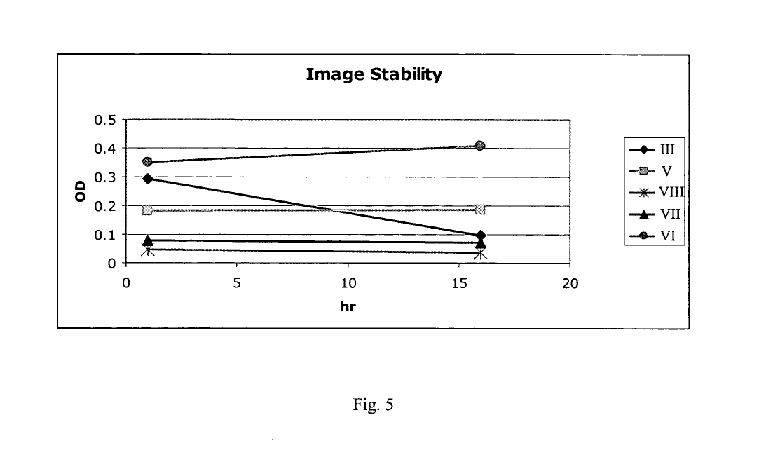

The change in sensitivity corresponding to changes in structure can be seen in FIG. 4, where various leuco dyes are compared in sensitivity to a dye having Structure III. It was found that dosimeters fabricated from leuco dyes having Structures V, VI, VII and VIII exhibited a color image upon radiation that was more stable than those fabricated from a dye having Structure III. That is, the colored image persisted within the irradiated dosimeter for a longer period of time. In this experiment, dosimeters containing equimolar amounts of the leuco dyes were irradiated and the absorbance at 633 nm was measured at 1 and 16 hours post-irradiation. As shown in FIG. 5, irradiated dosimeters containing either leuco dye having Structures V, VI, VII and VIII have color intensity which is essentially invariant during the test interval, while dosimeters containing leucomalachite green dye having Structure III demonstrated approximately 67% loss of absorbance intensity over the test time interval.

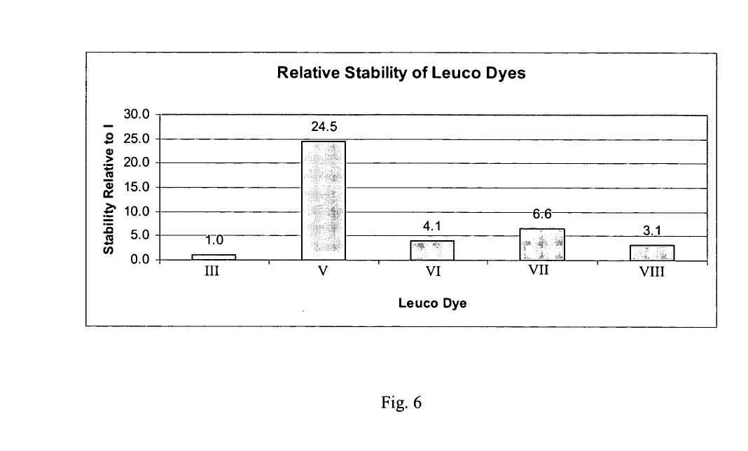

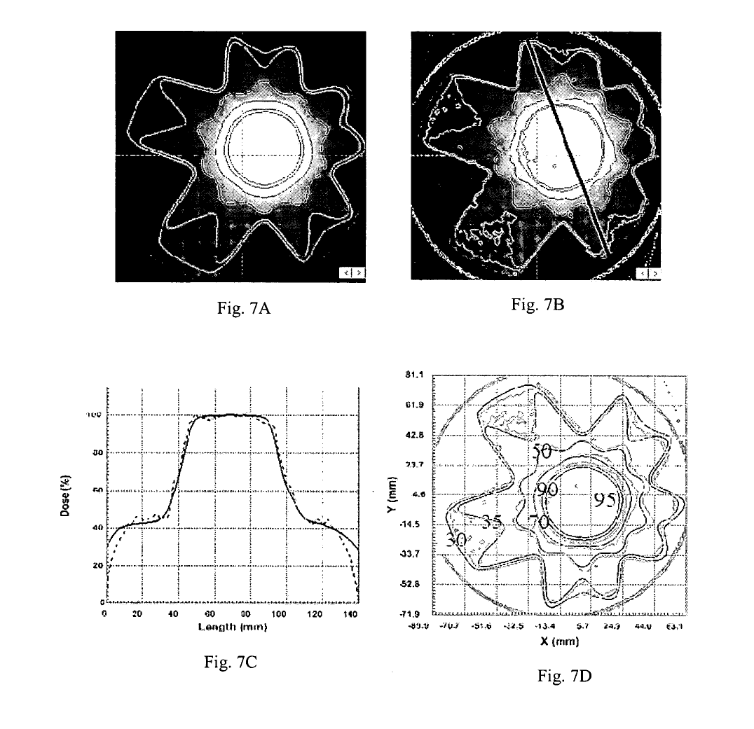

In FIG. 6, the stability of the colored image within irradiated dosimeters containing various leuco dyes is displayed. The relative stability is calculated using the relation Relative Stability=100*abs val(A_{LMG16-ALMG1}) 100*abs val(A₁₆-A₁) where abs val=absolute value; A_{LMG16}=absorbance of Structure II at 16 hr; A_{LMG1}=absorbance of Structure II at 1 hr; A₁₆=absorbance of leuco dye at 16 hr; A₁=absorbance of leuco dye at 1 hr. This data reflects the color stability of the images relative to the parent dye having Structure III. Dosimeters containing leuco dyes having Structures V, VI, VII, and VIII all formed color images upon irradiation which changed in intensity less than the dosimeter formed from leuco dye having Structure III.

Therefore each of the dyes having Structures V, VI, VII, and VIII have a relative stability value greater than unity. It is clearly shown that modifications to Structure III can have a significant impact upon both the sensitivity and the stability of dosimeters made according to the present invention.

It will be appreciated that structural modifications exhibited by the dyes having Structures III-VIII have surprisingly desirable properties upon the parameters of the dosimeters of the invention. Other derivatives described by general Structure I and Structure II can impart desirable properties to the dosimeters of the invention.

It will be appreciated that the leuco dyes of the invention are soluble in one or more of the prepolymer reactants of other optical plastics, and therefore can be distributed homogeneously throughout other solid optical plastics. It will also be appreciated that the leuco dyes of the invention are compatible with one or more prepolymer reactants of other optical plastics, and can give acceptable color transformation upon irradiation. Such other optical plastics can then form dosimeters which are within the scope of the invention.

In one embodiment of the present invention, the leuco dye of the present invention is dissolved in Prepolymer A prior to mixing with Prepolymer B and a catalyst. A homogenous distribution of the leuco dye throughout the dosimeter product results. In another embodiment, the leuco dye of the present is dissolved in an organic solvent. The resulting solution is then admixed with Prepolymer A, Prepolymer B, and a catalyst. This also results in a homogeneous distribution of the leuco dye throughout the dosimeter product. Solvents which have been discovered to be useful in formulating dosimeters of the present invention include ethyl acetate, butyl acetate, phenyl acetate, benzene, toluene, xylene, cyclohexane, chloroform, dichloromethane, carbon tetrachloride, dimethyl sulfoxide, N,N-dimethylformamide, methyl tert-butyl ether, phenyl ether, trichloroethane, and ethylene dichloride. It will be appreciated that several other organic solvents could be utilized for the purpose outlined here, and that dosimeters fabricated utilizing such other solvents are within the scope of the invention. A useful range of concentration of leuco dyes of the present invention is between about 0.1% and about 5.0% w/w of the entire formulation used to make dosimeters.

In another aspect of the present invention, a method of planning and optimizing complex radiation therapy is disclosed in which a water-insoluble substantially transparent shaped solid dosimeter having one or more water-insoluble reporter molecules distributed homogeneously throughout is subjected to a field of radiation, resulting in the formation of a colored image within the volume of the dosimeter. The colored image is analyzed by computerized optical scanning of the volume of the dosimeter. The analysis is comprised of detection of the difference in optical absorbance of light by the colored image and the optical absorbance of light by non-irradiated portions of the dosimeter. The tomographic process comprises detection of the difference in absorbances, rotating the dosimeter through a discreet angle, repeating the detection of the difference in absorbances, repeating the rotation and detection of the differences in absorption a plurality of times, and reconstructing the colored image by a computerized process.

In one aspect, the present invention, relates to a method of reconstructing a radiation field comprising the steps of contacting a shaped solid dosimeter device comprising substantially transparent optical plastic and one or more triarylmethane leuco dyes distributed homogeneously within the device with a radiation field, for inducing a color image within the dosimeter; detecting absorbance of light by the color image relative to non-irradiated portions of the dosimeter for measuring said color image; storing the measurement of the color image in a computer memory; rotating the dosimeter through a discrete angle; and repeating the above steps a plurality of times; and reconstructing the radiation field by computerized tomography manipulation of the stored measurements of the color image.

Another aspect of the present invention relates to a method of planning, verifying, and optimizing delivery of a radiation field to a patient for 3D conformal radiation therapy comprising the steps of: contacting a shaped solid dosimeter device having a clinically relevant volume comprising substantially transparent optical plastic and one or more triarylmethane leuco dyes homogeneously within the device with a radiation field, for inducing a color image within the dosimeter; detecting absorbance of light by the color image relative to non-irradiated portions of the dosimeter for measuring the color image; storing the measurement of the color image in a computer memory; rotating the dosimeter through a discrete angle; repeating the above steps a plurality of times; and reconstructing the radiation field by computerized tomography manipulation of the stored measurements of the color image.

Another aspect of the present invention relates to a method of planning, verifying, and optimizing the delivery of a radiation field to a patient for 3D conformal radiation therapy comprising the steps of: placing within an anthropomorphic phantom a shaped solid dosimeter device having a clinically relevant volume comprising substantially transparent optical plastic and one or more triarylmethane leuco dyes homogeneously within the device, contacting the phantom and the dosimeter device with a radiation field, for inducing a color image within the dosimeter; measuring the color image by detecting the absorbance of light by the color image relative to non-irradiated portions of the dosimeter; storing the measurement in a computer memory; rotating the dosimeter through a discrete angle; repeating the detection of absorbance and the rotation and the storage a plurality of times; and reconstructing the radiation field by computerized tomography manipulation of the stored measurements of the color image.

Applications in which the 3D dosimeter measuring non-uniform penetrating radiation of the present invention can be used include, but are not limited to, diagnostic imaging in human health and disease, and directed radiation therapy in medicine. Directed radiation therapy includes, but is not limited to, dose planning, dose mapping, dose calibration, dose simulation, dose calculation, dose optimization and dose verification systems for 3D Conformal Radiation Therapy. For the purpose of this application, conformal radiation therapy is defined as a computer-guided process wherein external beam radiation is modulated by one or more of several possible methods to conform to the precise 3D structure of diseased tissue, thereby delivering an optimal dose to target structures while minimizing dosing of nearby normal tissues. An example of 3D conformal radiation therapy is Intensity-Modulated Radiation Therapy (IMRT). Other applications in which the dosimeter of the present invention can be used include Ophthalmic Applicators, Tissue-metal dental interfaces, Stereotactic Radiosurgery, Gamma Knife Radiosurgery, Image guided radiotherapy (IGRT), Adaptive Radiation Therapy (ART), Four-dimensional radiotherapy (4DRT), Adjuvant Therapy, Palliative treatment, Neoadjuvant therapy, Intraoperative radiation therapy (IORT), High-dose Protein inactivation, measurement of clinical proton beams, Intracavity Brachytherapy, Seed Implant Brachytherapy, Carbon Ion Therapy, Intravascular Brachytherapy, Photodynamic Laser Therapy, thermal neutron therapy, Boron Neutron Capture Therapy, and the implementation of therapeutic radionuclides for bone palliation. Uniform penetrating radiation is herein defined as radiation which is spatially invariant over the time of the exposure. Non-uniform radiation is herein defined as radiation which is attenuated, modulated, varied, or altered in intensity, duration, geographic distribution, dose, or power by means including, but not limited to manipulation of beam sizes, beam arrangements, dose power, dose duration, dose protocols, and manipulation of leaves, collimators, windows, apertures, gantry, or treatment table.

An advantage of the present invention is that it provides a 3D dosimetric map formed by irradiation which exhibits a high degree of resolution. In general, an advantage of the present invention is that it provides a 3D dosimetric map formed by irradiation which exhibits a high degree of image stability and integrity. Another advantage of the present invention is that it provides a 3D dosimetric map formed by irradiation which upon analysis by one of several means known to those skilled in the art accurately reconstructs the irradiation event. Another advantage of the present invention is that it provides a substantially transparent plastic dosimeter which can be fabricated into any shape, is homogeneous across all dimensions, and can be irradiated and analyzed without the aid of a container. Another advantage of the present invention is that it provides a substantially transparent plastic dosimeter which contains a 3D dosimetric map formed by irradiation which is stabilized loss of data due to premature fading, bleaching, or whitening of the contained image. Another advantage of the present invention is that it provides a substantially transparent plastic dosimeter which contains a 3D dosimetric map formed by irradiation which is stabilized by elements of the invention against loss of data due to unintended changes in the optical attributes of the polymeric media due to exposure to the environment. Another advantage of the present invention is that it provides a robust and safe process of manufacture which can be practiced without the need to exclude oxygen. Another advantage of the present invention is that it provides a dosimeter capable of accurately measuring the absolute dose of radiation.

The invention can be further illustrated by the following examples thereof, although it will be understood that these examples are included merely for purposes of illustration and are not intended to limit the scope of the invention unless otherwise specifically indicated. All percentages, ratios, and parts herein, in the Specification, Examples, and Claims, are by weight and are approximations unless otherwise stated.

### EXAMPLES

Materials used were obtained from the following manufacturers: Crystal Clear 206 Part A, 200 Part B, 220 Part A, 220 Part B from Smooth-On, Inc., Easton, Pa.; carbon tetrachloride, chloroform, bromochloromethane, tribromopropane, dibromohexane, benzoylmethylene blue, benzoyl peroxide, dichloromethane, butyl acetate, 4,4′-methylene bis(cyclohexyl isocyanate) (HMDI), azobis(isobutyrylnitrile) (AIBN), crystal violet lactone, leuco crystal violet, and leucomalachite green from Sigma-Aldrich, St. Louis, Mo.; Poly-Optic 14-70 Part A, Poly-Optic 14-70 Part B, and Optic Part 14X catalyst from PolyTech Development Corp, Easton, Pa.; Andur prepolymers (Andur AL62DP) from Anderson Development Co., Adrian, Mich.; Aliphatic Isocyanate Prepolymer and Z-8002 Polyol from Development Associates, North Kingstown, R.I.; Tolonate XIDT-70B polyisocyanate trimer from Rhodia PPMC; Tone 32B8 Polyol from Dow Chemical Co.; ConOptic 2020 Part A and ConOptic 2020 Part B from Cytec; Hisorb 944 and Hisorb 328 from LG Chem, Ltd.

### Example 1

Crystal Clear 206 Part A (250 g), Crystal Clear 206 Part B (200 g), carbon tetrachloride (180 g), Optic Part 14X catalyst (0.6 ml) and leucomalachite green (16 g) were blended thoroughly in a 1000 ml polyethylene beaker until the mixture was homogeneous. The mixture was then immediately poured into molds. The molds were either glass or polyethylene 30 ml vials. The filled molds were then placed under 60 psi pressure and maintained at 25° C. for 18 hours. This was achieved by arranging the molds within a pressure pot of the appropriate size and pressurizing with a compressor pump. At the end of this period, the solid dosimeters formed in polyethylene vials were removed from the molds.

### Example 2

In order to assess the dose response of the conversion of the leuco dye of the present invention to the amount of radiation encountered, dosimeters as described in Example 1 were subjected to graded doses of 145 kVp x-rays at three different dose rates, 0.66 Gy/min, 2.17 Gy/min, and 4.4 Gy/min, using Torrex 150D X-ray unit (EG&G, Long Beach, Calif.). The irradiated dosimeters were evaluated using the commercially available OCT-OPUS™ CT scanner (MGS Research, Inc., Madison, Conn.). In this analysis the conversion of leucomalachite green to the colored species is detected as an increase in optical density at 633 nm, a wavelength at which the leuco dye does not absorb. The transformation of leucomalachite green to its colored form was linear with dose and independent of dose rate.

### Example 3

4,4′-methylene bis(cyclohexyl isocyanate) (HMDI) (94 g), carbon tetrachloride (90 g), Crystal Clear 206 Part B (80 g), leucomalachite green (4.0 g) and Optic Part 14X catalyst (1.0 ml) were blended thoroughly in a 1000 ml polyethylene beaker. The mixture was then immediately poured into mold fabricated from a 500 ml cylindrical polyethylene beaker. The filled mold was pressurized as in Example 1 and incubated at 25° C. for 20 hours. The solid dosimeter was then removed from the mold.

### Example 4

HMDI (82 g), Andur 62 Polyol (12.8 g) carbon tetrachloride (43 g), a solution of leucomalachite green (1.5 g) in carbon tetrachloride (15 g), Crystal Clear 206 Part B (84 g), and Optic Part 14X catalyst (0.5 ml) were blended thoroughly in a 1000 ml polyethylene beaker. The mixture was then immediately poured into mold fabricated from a 500 ml cylindrical polyethylene beaker. The filled mold was pressurized as in Example 1 and incubated at 25° C. for 4 hours. The solid dosimeter was then removed from the mold.

### Example 5

HMDI (60 g), Andur 62 Polyol (47.5 g) carbon tetrachloride (35 g), a solution of leucomalachite green (1.5 g) in carbon tetrachloride (15 g), Crystal Clear 206 Part B (82 g), and Optic Part 14X catalyst (0.5 ml) were blended thoroughly in a 1000 ml polyethylene beaker. The mixture was then immediately poured into mold fabricated from a 500 ml cylindrical polyethylene beaker. The filled mold was pressurized as in Example 1 and incubated at 25° C. for 4 hours. The solid dosimeter was then removed from the mold.

### Example 6

HMDI (406 g), carbon tetrachloride (200 g), leucomalachite green (6.0 g), Crystal Clear 206 Part B (350 g), and Optic Part 14X catalyst (1.0 ml) were blended thoroughly in a 1000 ml polyethylene beaker. The mixture was then immediately poured into mold fabricated from a 1000 ml cylindrical polyethylene beaker. The filled mold was pressurized as in Example 1 and incubated at 25° C. for 20 hours. The solid dosimeter was then removed from the mold.

### Example 7

Anderson Development Inc. Andur AL62DP aliphatic Isocyanate Prepolymer (380 g), carbon tetrachloride (200 g), Z-8002 Part A Polyol (380 g), and leucomalachite green (6.0 g) were blended thoroughly in a 1000 ml polyethylene beaker. The mixture was then immediately poured into mold fabricated from a 1000 ml cylindrical polyethylene beaker. The filled mold was pressurized as in Example 1 and incubated at 25° C. for 20 hours. The solid dosimeter was then removed from the mold.

### Example 8

Tolonate XIDT-70B (70% solution in butyl acetate, 248.5 g), Crystal Clear 206 Part B (97 g), carbon tetrachloride (93 g), leucomalachite green (13 g) and Optic Part 14X catalyst (0.4 ml) were blended thoroughly in a 1000 ml polyethylene beaker. The mixture was then immediately poured into mold fabricated from a 1000 ml cylindrical polyethylene beaker. The filled mold was pressurized as in Example 1 and incubated at 25° C. for 20 hours. The solid dosimeter was then removed from the mold.

### Example 9

Crystal Clear 206 Part A (135 g), Crystal Clear 206 Part B (112 g), chloroform (80 g), leucomalachite green (10 g), and Optic Part 14X catalyst (0.5 ml) were blended thoroughly in a 500 ml polyethylene beaker. The mixture was then immediately poured into mold fabricated from a 500 ml cylindrical polyethylene beaker. The filled mold was pressurized as in Example 1 and incubated at 25° C. for 20 hours. The solid dosimeter was then removed from the mold.

### Example 10

Crystal Clear 206 Part A (135 g), Crystal Clear 206 Part B (112 g), chloroform (80 g), crystal violet lactone (10 g), and Optic Part 14X catalyst (0.5 ml) were blended thoroughly in a 500 ml polyethylene beaker. The mixture was then immediately poured into mold fabricated from a 500 ml cylindrical polyethylene beaker. The filled mold was pressurized as in Example 1 and incubated at 25° C. for 20 hours. The solid dosimeter was then removed from the mold.

### Example 11

Tinuvin (2.8 g) was dissolved in carbon tetrachloride (340.9 g) and HMDI (500.0 g) was added. This solution was blended thoroughly with Tone 32B8 (1624.1 g), leucomalachite green (32.4 g) and Optic Part 14X catalyst (1.0 ml). The mixture was then immediately poured into mold fabricated from an 800 ml cylindrical polyethylene beaker. The filled mold was pressurized as in Example 1 and incubated at 25° C. for 4 hours. The solid dosimeter was then removed from the mold.

### Example 12

Z-8002 Part B Isocyanate (200 g), Cytec Polyol (200 g), carbon tetrachloride (90 g), and leucomalachite green (9 g) were blended thoroughly. The mixture was then immediately poured into mold fabricated from an 800 ml cylindrical polyethylene beaker. The filled mold was pressurized as in Example 1 and incubated at 25° C. for 4 hours. The solid dosimeter was then removed from the mold.

### Example 13

Tolonate XIDT-70B (70% solution in butyl acetate, 250 g), Crystal Clear 206 Part B (100 g), carbon tetrachloride (94 g), leucomalachite green (9.4 g) and Optic Part 14X catalyst (0.4 ml) were blended thoroughly in a 1000 ml polyethylene beaker. The mixture was then immediately poured into mold fabricated from a 1000 ml cylindrical polyethylene beaker. The filled mold was pressurized as in Example 1 and incubated at 25° C. for 1.5 hours. The molded dosimeter was then warmed at 50° C. for 18 hours. The solid dosimeter was then removed from the mold.

### Example 14

Poly-Optic 14-70 Part A (100 g), Poly-Optic 14-70 Part B (125 g), carbon tetrachloride (39.8 g), and leucomalachite green (10.0 g) were blended thoroughly. The mixture was then immediately poured into mold fabricated from a 400 ml cylindrical polyethylene beaker. The filled mold was pressurized as in Example 1 and incubated at 25° C. for 24 hours. The solid dosimeter was then removed from the mold.

### Example 15

Poly-Optic 14-70 Part A (102.7 g), Poly-Optic 14-70 Part B (123.2 g), bromochloromethane (19.3 g), and leucomalachite green (10.0 g) were blended thoroughly. The mixture was then immediately poured into mold fabricated from a 400 ml cylindrical polyethylene beaker. The filled mold was pressurized as in Example 1 and incubated at 25° C. for 24 hours. The solid dosimeter was then removed from the mold.

### Example 16

Poly-Optic 14-70 Part A (103.4 g), Poly-Optic 14-70 Part B (126.6 g), tribromopropane (55.2 g), and leucomalachite green (10.0 g) were blended thoroughly. The mixture was then immediately poured into mold fabricated from a 400 ml cylindrical polyethylene beaker. The filled mold was pressurized as in Example 1 and incubated at 25° C. for 24 hours. The solid dosimeter was then removed from the mold.

### Example 17

Poly-Optic 14-70 Part A (104.8 g), Poly-Optic 14-70 Part B (126.0 g), 1,6-dibromohexane (47.6 g), and leucomalachite green (10.0 g) were blended thoroughly. The mixture was then immediately poured into mold fabricated from a 400 ml cylindrical polyethylene beaker. The filled mold was pressurized as in Example 1 and incubated at 25° C. for 24 hours. The solid dosimeter was then removed from the mold.

### Example 18

Poly-Optic 14-70 Part A (107.5 g), Poly-Optic 14-70 Part B (129.6 g), bromochloromethane (77.2 g), carbon tetrachloride (3.2 g) and benzoylmethylene blue (5.03 g) were blended thoroughly. The mixture was then immediately poured into mold fabricated from a 400 ml cylindrical polyethylene beaker. The filled mold was pressurized as in Example 1 and incubated at 25° C. for 24 hours. The solid dosimeter was then removed from the mold.

### Example 19

Poly-Optic 14-70 Part A (45 g), Poly-Optic 14-70 Part B (45 g), tetrahydrofuran (5.0 ml), benzoyl peroxide (1.0 ml), and leucomalachite green (4.0 g) were blended thoroughly. The mixture was then immediately poured into mold fabricated from a 400 ml cylindrical polyethylene beaker. The filled mold was pressurized as in Example 1 and incubated at 25° C. for 24 hours. The solid dosimeter was then removed from the mold.

### Example 20

Poly-Optic 14-70 Part A (80 g), Poly-Optic 14-70 Part B (100 g), tetrahydrofuran (7.0 ml), a solution of azobis(isobutyrylnitrile) (0.29 g) in tetrahydrofuran (0.2 ml), and leucomalachite green (4.0 g) were blended thoroughly. The mixture was then immediately poured into mold fabricated from a 400 ml cylindrical polyethylene beaker. The filled mold was pressurized as in Example 1 and incubated at 25° C. for 24 hours. The solid dosimeter was then removed from the mold.

### Example 21

Crystal Clear 206 Part A (100 g), Crystal Clear 206 Part B (100 g), tetrachloroethane (47.9 g), Pergascript Blue 1-2R (3 g), were blended thoroughly in a 500 ml polyethylene beaker. The mixture was then immediately poured into mold fabricated from a 500 ml cylindrical polyethylene beaker. The filled mold was pressurized as in Example 1 and incubated at 25° C. for 72 hours. The solid dosimeter was then removed from the mold.

### Example 22

Crystal Clear 206 Part A (150 g), Crystal Clear 206 Part B (150 g), tetrachloroethane (112 g), Pergascript Blue SRB-P (10 g), were blended thoroughly in a 500 ml polyethylene beaker. The mixture was then immediately poured into mold fabricated from a 500 ml cylindrical polyethylene beaker. The filled mold was pressurized as in Example 1 and incubated at 25° C. for 72 hours. The molded dosimeters were then warmed at 50° C. for 6 hours. The solid dosimeter was then removed from the mold.

### Example 23

ConOptic 2020 Part A (100 g), ConOptic 2020 Part B (100 g), tetrachloroethane (45 g), and leucomalachite green (3.9 g) were blended thoroughly in a 500 ml polyethylene beaker. The mixture was then immediately poured into 30 ml glass vials. The filled molds were pressurized as in Example 1 and incubated at 25° C. for 72 hours. The dosimeters were irradiated as in Example 2 at 4.4 Gy/min, resulting in the development of a clearly visible dosimetric map. The dosimeters were then warmed in an oven at 50o C for 20 minutes. During this time the exposed areas of the dosimeters were completely bleached and the dosimetric data was erased. The irradiation-bleaching process was repeated twice more on the same set of dosimeters. Each time the irradiation resulted in a clearly visible dosimetric map, and the bleaching completely erased the data.

### Example 24

Crystal Clear 206 Part A (260 g), Crystal Clear 206 Part B (200 g), tetrachloroethane (104 g), leucomalachite green (10 g), Optic Part 14X catalyst (0.2 ml), and Hisorb 944 were blended thoroughly in a 1000 ml polyethylene beaker. The mixture was then immediately poured into mold fabricated from a 1000 ml cylindrical polyethylene beaker. The filled mold was pressurized as in Example 1 and incubated at 25° C. for 20 hours. The solid dosimeter was then removed from the mold.

### Example 25

Crystal Clear 206 Part A (1048 g), Crystal Clear 206 Part B (800 g), tetrachloroethane (480 g), leucomalachite green (40 g), Optic Part 14X catalyst (1.0 ml), and Hisorb 328 (2 g) were blended thoroughly in a 2000 ml polyethylene beaker. The mixture was then immediately poured into a polyethylene mold having the size and shape of the average human brain. The filled mold was pressurized as in Example 1 and incubated at 25° C. for 36 hours. The molded dosimeter was warmed to 40° C. for 48 hours. The solid dosimeter was then removed from the mold.

### Example 26

HMDI (280 g), Crystal Clear 206 Part B (242 g). methylene chloride (162 g), Pergascript Blue SRB-P (16 g), Optic Part 14X catalyst (0.5 ml), were blended thoroughly in a 1000 ml polyethylene beaker. The mixture was filtered through a 10 μm filter and pressurized as in Example 1 and incubated at 25° C. for 20 hours.

### Example 27

HMDI (66 g), Crystal Clear 206 Part B (58 g), chloroform (10 g), carbon tetrachloride (27 g), leuco crystal violet (3.8 g), Optic Part 14X catalyst (0.2 ml), were blended thoroughly in a 100 ml polyethylene beaker. The mixture was filtered through a 10 μm filter and pressurized as in Example 1 and incubated at 25° C. for 20 hours.

### Example 28

Desmodur N3300 (14 g), Desmophen 670A80 (36 g), naphthyl-substituted LMG derivative V (1.5 g), methylene chloride (2.75 g). carbon tetrabromide (0.275 g), Optic Part 14X catalyst (2 drops), were blended thoroughly and poured into glass scintillation vials and pressurized as in Example 1 and incubated for 20 hours.

### Example 29

Desmodur N3300 (14 g), Desmophen 670A80 (36 g), methyl-substituted LMG derivative IV (1.5 g), toluene (3.75 g), carbon tetrabromide (0.275 g), Optic Part 14X catalyst (4 drops), were blended thoroughly and poured into glass scintillation vials and pressurized as in Example 1 and incubated for 20 hours.

### Example 30

Desmodur N3300 (1200 g), Desmophen NH1520 (1880 g), LMG 1 (33 g), carbon tetrabromide (33 g) and phenyl acetate (246 g), were blended thoroughly and poured into a 600 mL (10 cm diameter) and 4000 mL cylindrical (16 cm diameter) polyethylene containers. The 16 cm diameter by 11 cm height polyurea dosimeter was used to record the delivered 3D dose from a 3D conformal treatment plan. The recorded 3D dose distribution in the dosimeter was reconstructed from the optical-CT scan of the dosimeter via the algebraic reconstruction technique (ART). Comparison of dose distributions between the optical measurements, calculation in treatment plan, and GAFCHROMIC® EBT film measurement was performed. Results portrayed in the Figure show good agreement between them from high dose region (95% isodose line) through low dose region (30% isodose line).

It is to be understood that the above-described embodiments are illustrative of only a few of the many possible specific embodiments, which can represent applications of the principles of the invention. Numerous and varied other arrangements can be readily devised in accordance with these principles by those skilled in the art without departing from the spirit and scope of the invention.

What is claimed is:

1. A shaped solid dosimeter device comprising substantially transparent optical plastic and distributed homogeneously within said device one or more leuco dyes having the structure 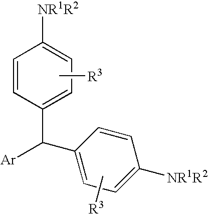
wherein
R1 is H, C₁-C₆ alkyl, or phenyl;
R2 is H, C₁-C₆ alkyl, or phenyl;
R3 is H, C₁-C₆ alkyl, or phenyl;
and Ar is a carbocyclic aromatic or a 5, 6, or 7-membered heterocyclic ring containing one or two heteroatoms selected from N, O, and S.

2. The dosimeter of claim 1 wherein the optical plastic is a substantially transparent polymeric material which forms and cures at or below about 60° C.

3. The dosimeter of claim 1 wherein the optical plastic is selected from the group consisting of polyurethane and polyurea.

4. The dosimeter of claim 1 wherein the optical plastic is polyurethane.

5. A shaped solid dosimeter device comprising substantially transparent optical plastic and distributed homogeneously within said device one or more leuco dyes having a structure of 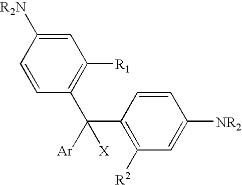
wherein
R is methyl, ethyl, propyl, butyl, or phenyl;
R¹ is H, C₁-C₆ alkyl, or phenyl;
R² is H, C₁-C₆ alkyl, or phenyl;
Ar is phenyl, o-tolyl, 2,6-dimethylphenyl, 2-methoxyphenyl, 4-methoxyphenyl, 2-hydroxyphenyl, 4-hydroxyphenyl, 4-phenylaminophenyl, 4-diphenylaminophenyl, 2,4-dimethoxyphenyl, 2-fluoro-4-methoxyphenyl, 1-napthyl, 4-dimethylamino-1-napthyl, 4-diethylamino-1-napthyl, 4-phenylaminophenyl-1-napthyl, 4-diphenylaminophenyl-1-napthyl, 2-napthyl, anthracene-9-yl, 2-fluorophenyl, 2-chlorophenyl, 2-bromophenyl, 2,6-difluorophenyl, 2-methoxyphenyl, 4-dimethylaminophenyl, 4-diethylaminophenyl, pentafluorophenyl, furan-2-yl, furan-3-yl, 2-thiophenyl, 4-thiophenyl, thiophene-2-yl, thiophene-3-yl, 2-indolyl, 3-indolyl, 5-indolyl, 2-pyridyl, 3-pyridyl, 4-pyridyl, imidazol-2-yl, 2-biphenyl, 3-biphenyl, 4-biphenyl, pyrrole-2-yl, pyrrole-3-yl, imidazol-4(5)-yl, or 4-(1H-imidazol-1-yl)phenyl; and
X is H, nitrilo, hydroxyl, azido, pyrrole-1-yl, imidazol-2-yl, methoxy, ethoxy, tert-butoxy, phenoxy, 4-fluorophenoxy, 4-methoxyphenoxy, benzyl, p-methoxybenzyl, methylthio, or phenylthio;
and the concentration of leuco dye within the dosimeter is from about 0.1% to about 5.0% w/w.

6. The dosimeter of claim 5 wherein the optical plastic is a substantially transparent polymeric material which forms and cures at or below about 60° C.

7. The dosimeter of claim 5 wherein the optical plastic is selected from the group consisting of polyurethane and polyurea.

8. The dosimeter of claim 5 wherein the optical plastic is polyurethane.

9. The dosimeter of claim 5 wherein the optical plastic is polyurea.

10. A shaped solid dosimeter device comprising an optical polymer selected from the group consisting of polyurethane and polyurea, distributed homogeneously within one or more leuco dyes having a structure of 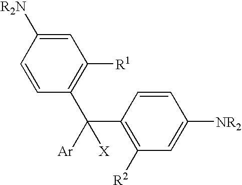
wherein
R is methyl;
R₁ is H or methyl;
R₂ is H or methyl;
X is H;
Ar is phenyl, 4-dimethylaminophenyl, 2-fluorophenyl, 2,6-difluorophenyl, 2-bromophenyl, 2-methylphenyl, 2,6-dimethylphenyl, 2-methoxypheny, 1-napthyl, or 9-anthracenyl;
and the concentration of leuco dye within the dosimeter is from about 0.1% to about 5.0% w/w.

11. The dosimeter of claim 10 wherein the optical polymer is polyurethane.

12. The dosimeter of claim 10 wherein the optical polymer is polyurea.

13. A shaped solid dosimeter device comprising polyurethane and one or more leuco dyes having the structure of 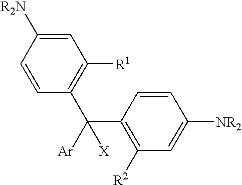
wherein
R is methyl;
R₁ is H;
R₂ is H;
X is H; and
Ar is selected from the group consisting of phenyl, 4-dimethylaminophenyl, 2-fluorophenyl, 2-methylphenyl, 2,6-dimethylphenyl, 2-methoxypheny, and 1-napthyl;
and the concentration of leuco dye within the dosimeter is from about 0.1% to about 5.0% w/w.

14. A shaped solid dosimeter device comprising polyurea and one or more leuco dyes selected from a set of compounds having the structure of 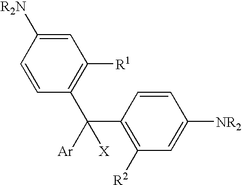
wherein
R is methyl;
R₁ is H;
R₂ is H;
X is H; and
Ar is selected from the group consisting of phenyl, 4-dimethylaminophenyl, 2-fluorophenyl, 2-methylphenyl, 2,6-dimethylphenyl, 2-methoxypheny, and 1-napthyl;
and the concentration of leuco dye within the dosimeter is from about 0.1% to about 5.0% w/w.

15. The dosimeter of claim 1, 5, 10, 13, or 14 wherein the dosimeter has a volume of about 1 cm³ to about 40 liters.

16. The dosimeter of claim 1, 5, 10, 13, or 14 wherein the dosimeter has a substantially cylindrical shape with a diameter from about 5 mm to about 20 cm and a height of about 20 mm to about 40 cm.

17. A shaped solid dosimeter device comprising polyurethane and a leuco dye having the structure of

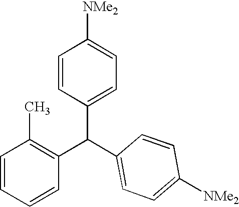

18. A shaped solid dosimeter device comprising polyurethane and a leuco dye having the structure of

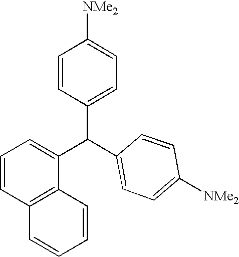

19. A method of reconstructing a radiation field comprising the steps of:
(a) contacting a shaped solid dosimeter device comprising substantially transparent optical plastic and one or more triarylmethane leuco dyes distributed homogeneously within said device with a radiation field, for inducing a color image within the dosimeter;
(b) detecting absorbance of light by said color image relative to non-irradiated portions of said dosimeter for measuring said color image;
(c) storing the measurement of said color image in a computer memory;
(d) rotating said dosimeter through a discrete angle;
(e) repeating a plurality of times steps b-d; and
(f) reconstructing said radiation field by computerized tomography manipulation of said stored measurements of said color image.

20. A method of planning, verifying, and optimizing delivery of a radiation field to a patient for 3D conformal radiation therapy comprising the steps of:
(a) contacting a shaped solid dosimeter device having a clinically relevant volume comprising substantially transparent optical plastic and one or more triarylmethane leuco dyes homogeneously within said device with a radiation field, for inducing a color image within the dosimeter;
(b) detecting absorbance of light by said color image relative to non-irradiated portions of said dosimeter for measuring said color image;
(c) storing the measurement of said color image in a computer memory;
(d) rotating said dosimeter through a discrete angle;
(e) repeating a plurality of times steps b-d; and
(f) reconstructing said radiation field by computerized tomography manipulation of said stored measurements of said color image.

21. A method of planning, verifying, and optimizing the delivery of a radiation field to a patient for 3D conformal radiation therapy comprising the steps of:
(a) placing within an anthropomorphic phantom a shaped solid dosimeter device having a clinically relevant volume comprising substantially transparent optical plastic and one or more triarylmethane leuco dyes homogeneously within said device, contacting said phantom and said dosimeter device with a radiation field, for inducing a color image within the dosimeter;
(b) measuring the color image by detecting the absorbance of light by said color image relative to non-irradiated portions of said dosimeter;
(c) storing said measurement in a computer memory;
(d) rotating said dosimeter through a discrete angle;
(e) repeating said detection of absorbance and said rotation and said storage a plurality of times; and
(f) reconstructing said radiation field by computerized tomography manipulation of said stored measurements of said color image.

22. A shaped solid dosimeter device comprising substantially transparent optical plastic and distributed homogeneously within said device one or more water-insoluble color forming reporter molecules, wherein a color image forms upon radiation.
